(19) United States
(12) Patent Application Publication
(10) Pub. No.: US 2016/0192516 A1
(43) Pub. Date: Jun. 30, 2016

(54) Mobile Electronic Device Armband Carrier

(71) Applicant: Glenn R. Thompson, Colts Neck, NJ (US)

(72) Inventor: Glenn R. Thompson, Colts Neck, NJ (US)

(21) Appl. No.: 14/587,111

(22) Filed: Dec. 31, 2014

(51) Int. Cl. H05K 5/00; A45C 11/00; H04B 1/3888

(52) U.S. Cl. CPC H05K 5/0086; H04B 1/3888; A45C 11/00; A45C 2011/001

(57) ABSTRACT

An Armband composed of a stretchable compression, see-through material fabrication incorporates a pocket for receiving a mobile electronic device in an arrangement where the device's display screen is inserted laterally into the pocket along an inside surface of a user's forearm to be easily viewed by a wearer of the device, either along the left inside surface or right inside surface of the forearms by a wearer when grasping a wheel of a motor vehicle, the handlebars of a motorcycle or bicycle, or the reins of a horse.

### CROSS-REFERENCE TO RELATED APPLICATIONS

None.

### STATEMENT REGARDING FEDERALLY SPONSORED RESEARCH OR DEVELOPMENT

None.

### REFERENCE TO A MICROFICHE APPENDIX

None.

### BACKGROUND OF THE INVENTION

1. Field of the Invention

This invention relates to mobile electronic device armband carriers, in general, and to such armbands especially beneficial for motorists, cyclists and horsemen, in particular.

2. Description of the Related Art

As will be appreciated, most people today won't leave their house without their smartphone. Men throw them into their pockets, and women put them in their purses. Sometimes, however, the women don't wish to carry a purse or their outfit may be bereft of pockets—or maybe they're wearing skinny jean and are worried about the phone bending. Because thigh holsters and like smartphone carriers are bulky, women oftentimes turn to fanny packs, or leather belts that contain external carriers for holding a phone. In other instances, the men and women may just carry their phones in their hands.

But, as will also be appreciated, problems become magnified when the reason for leaving the house is to drive an automobile, a sport utility vehicle or a truck. There, sitting down, driving, makes it more difficult to reach for, or otherwise access, the smartphone on one's person to receive or respond to a voice call or text message. To deal with such situations, many drivers simply place their smartphones on the seat besides them, on the dashboard, or in one of the several storage compartments provided.

It is well known, however, that the popularity of these types of mobile electronic devices have led to several unintended and even dangerous consequences. In fact, it has been established that mobile communications are linked to a significant increase in distracted driving, resulting in injury and loss of life. In particular, the National Highway Traffic Safety Administration in the United States reports that driver distraction is the cause of eighteen percent and more of all fatal crashes, and crashes resulting in injury. Other studies have shown that some forty percent of teens say that they have been in a car when the driver used a cellphone in a way that put people in danger. Other analyses found that text messaging while driving created a crash risk approximately 23 times worse then driving while not distracted—and that for drivers aged 18 to 20, approximately eleven percent who were involved in an automobile accident admitted that they were sending or receiving text messages when they crashed.

As a result, several Government Agencies have been working with industry and safety organizations to inform and educate the public about the dangers of distracted driving and to identify and facilitate the development of innovative technologies that could reduce the incidence of distracted driving. This becomes all the more important from studies which report that texting while driving is about 6 times more likely to cause an accident than driving intoxicated, that it makes one 23 times more likely to crash, that it is the same as driving blind for 5 seconds at a time and that it slows brake reaction speed by eighteen percent. Other statistics show similar results with respect to answering and carrying on cellphone conversations while driving.

As will become clear from the following description, the Armband Carrier of the present invention is directed toward reducing such incidence of distracted driving—which becomes all the more important in view of the fact that there is no National ban on texting or using wireless phone technology while driving, or requiring hands-free use of wireless phones while behind the wheel.

### OBJECTS OF THE PRESENT INVENTION

It is an object of the present invention, therefore, to provide an armband carrier for a mobile electronic device for general purpose wearing.

It is an object of the present invention, also, to provide such an armband carrier for use by a motorist—whether operating an automobile, a sport utility vehicle, or a truck.

It is another object of the invention to provide an armband carrier of this type for use by a cyclist (motorcycle, bicycle, etc.) and by a horseman.

It is a further object of the invention to provide such an armband carrier of this type sized and arranged for ease of use for mobile voice communication purposes while traveling about—and even during just such activities as walking, jogging, running and gymnasium activities.

It is yet an additional object of the invention to provide this armband carrier in a manner easy to alert a user of the receipt of a text message so as to pull off the road and stop to read and reply to it where warranted.

And, it is an objective of the present invention to achieve all the foregoing with a minimum amount of distraction to an otherwise engaged user.

Similarly, it is an object of the invention to apply its teaching in instances where the mobile electronic device is only of a type to play previously stored music and voice selection without voice or text communication attributes.

### SUMMARY OF THE INVENTION

As will become clear from the following description, these objectives are achieved through the use of an armband aligned to rest on the inside surface of a wearer's forearm, either on the inside of the left forearm for a right-handed person or on the inside of the right forearm for a left-handed person, thereby being closer and more easily accessible to a user holding a steering wheel, the handles of a motorcycle or bicycle, or the reins of a horse, as the case may be.

As will be seen below, the armband of the invention comprises a sleeve having first and second open opposing ends, first and second inner facing surfaces each overlain by an outer surface, and an inside pocket accessible by one of the first and second open ends. In accordance with the invention, the sleeve is of a length to extend along the forearm of the wearer, from the wrist area towards the elbow area, with the pocket being sized to receive within a mobile electronic device having a back surface adjacent one of the first and second inner facing surfaces, and a display screen adjacent the other of the first and second inner facing surfaces. So as to retain the sleeve in place during these types of activities, the sleeve is composed of a stretchable compression, see-through material fabrication, and with the mobile electronic device adapted to be inserted laterally into the pocket with its display screen aligned along the inside surface of either of the user's forearm.

In a preferred embodiment of the invention, the first end of the sleeve is of a larger opening than the opposing second end, and the pocket is sized to receive a mobile electronic communication device capable of receiving text messages and voice communications. In this embodiment, furthermore, the sleeve is composed of a washable, stretchable compression, see-through garment material fabrication, such as one composed of a fiber embedded nylon. For ease of usage, the sleeve's pocket is sized to receive the mobile electronic communication device inserted through the larger, first open end of the sleeve into the pocket, with the sleeve's second open end being proximate to the wrist of the wearer of the armband.

### BRIEF DESCRIPTION OF THE DRAWINGS

These and other features of the present invention will be more clearly understood from a consideration of the following description, taken in connection with the accompanying Drawings, in which:

FIG. 1 is a perspective view of a smartphone armband carrier of the invention;

FIG. 2 is a top plan view thereof;

FIG. 3 is a bottom plan view of the armband carrier;

FIGS. 4 and 5 are left and right side views, respectively, of the carrier;

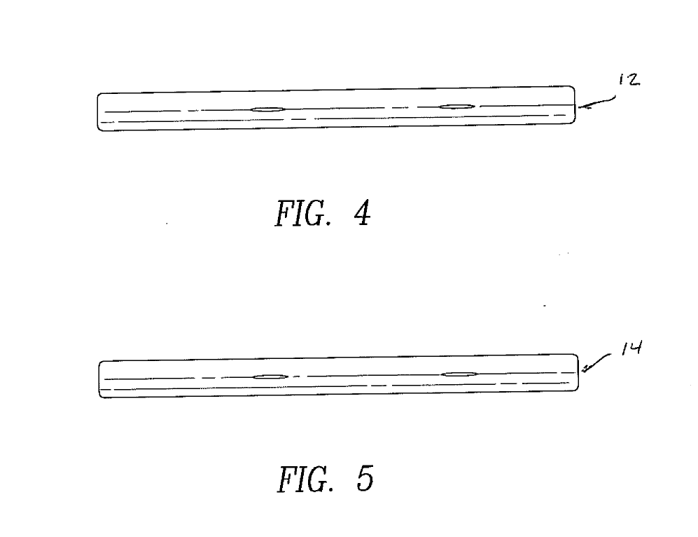

FIGS. 6 and 7 are bottom and top views, respectively, of the armband carrier;

FIG. 8 is a perspective view of the armband carrier ready to receive to smartphone for use;

FIG. 9 is a perspective view of a right-handed wearer's left arm, palm-view up, with the smartphone in place in the carrier; and

FIG. 10 is an illustration of the armband carrier and smartphone as worn by a user thereof.

### DETAILED DESCRIPTION OF THE INVENTION

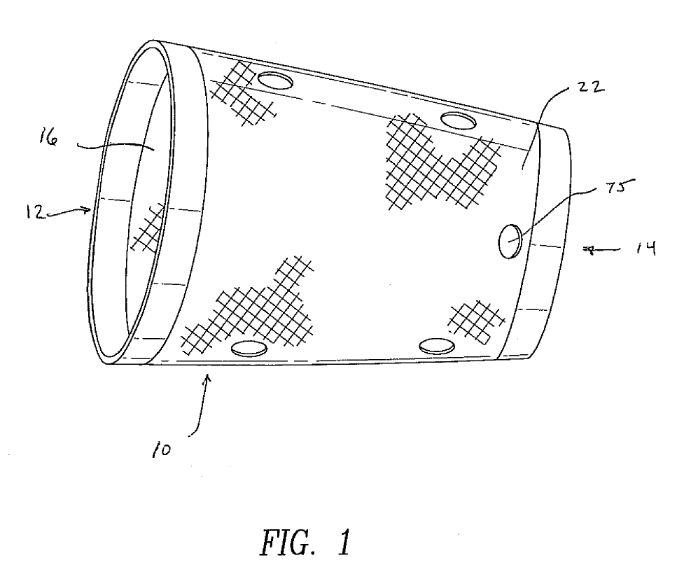

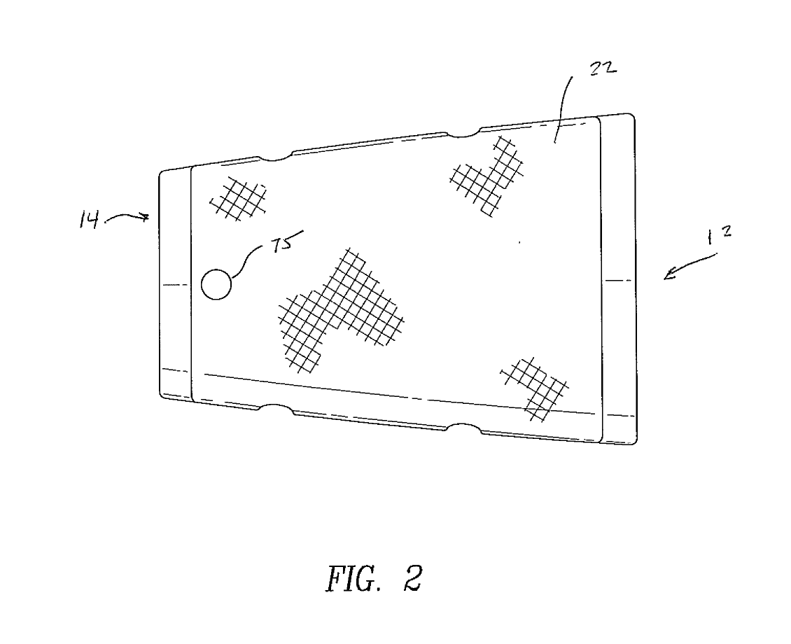

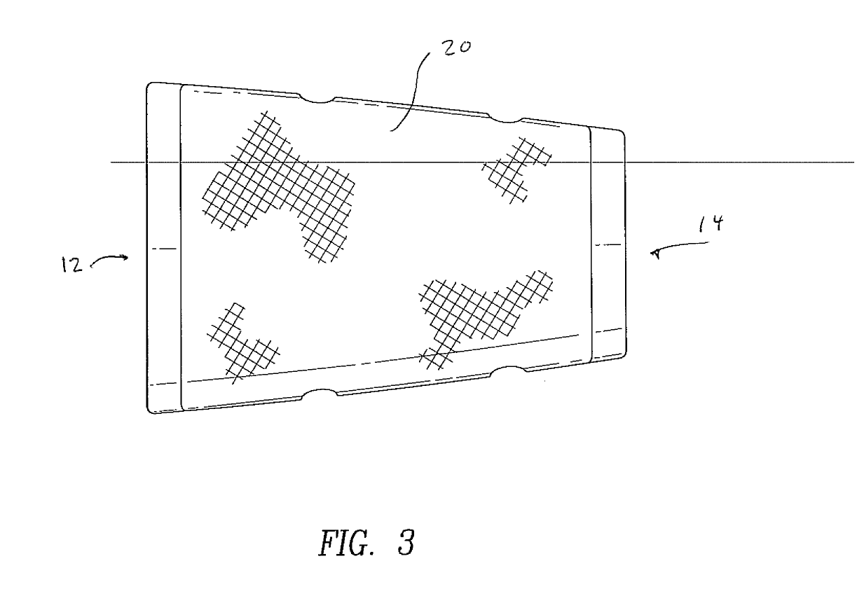

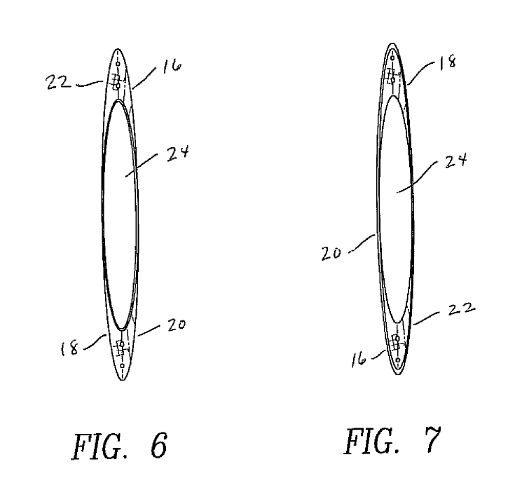

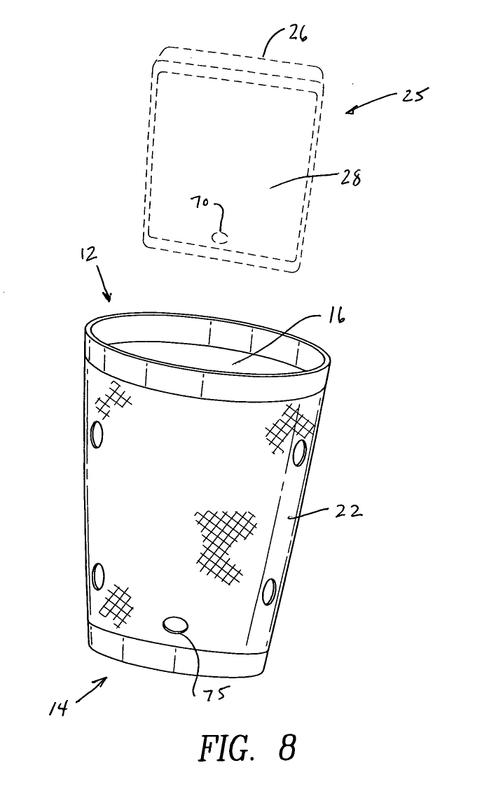

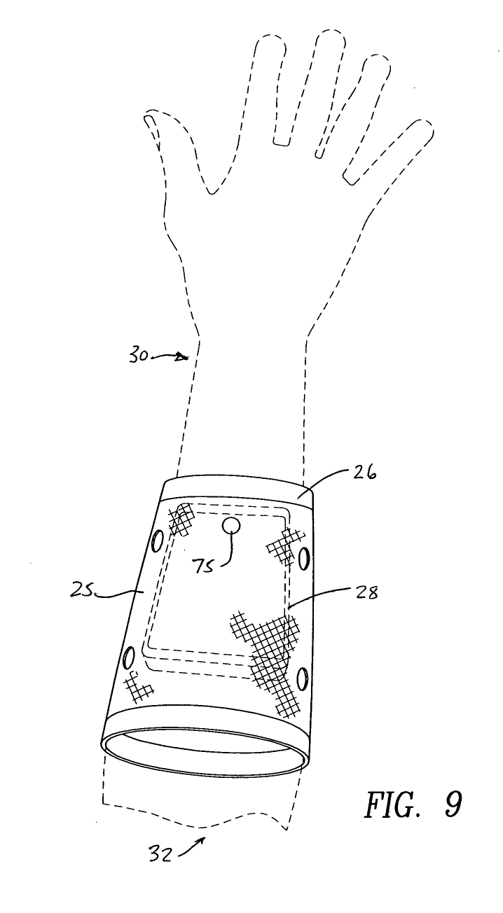

In the Drawings, the armband carrier of the invention includes a sleeve 10 having first and second open opposing ends 12, 14, first and second inner facing surfaces 16, 18, and overlying outer surfaces 20, 22. An inside pocket accessible for a smartphone through one of the first and second open opposing ends is included, illustrated in FIGS. 6 and 7 as 24, preferably accessible through the open end 12. As illustrated in FIGS. 1-3 and 8-9, the first open end 12 of the sleeve 10 is of a larger opening than the opposite second open end 14—and that the pocket 24 is sized to receive the smartphone or like mobile electronic device 25 having a back surface and a display screen, respectively shown at 26 and 28 in FIGS. 8-9. In a preferred embodiment of the invention, the pocket is sized to receive a mobile electronic communication device of the type capable of receiving both text messages and voice communications.

In accordance with the invention, the sleeve 10 is composed of a stretchable compression, see-through material fabrication, which in a preferred embodiment of the invention is a washable see-through garment material, such as a fiber embedded nylon. As shown, in FIG. 9, the sleeve 10 is of a length to extend along a forearm of the wearer, preferably from adjacent the wrist area 30 towards the elbow area 32. With the sleeve being composed of this stretchable compression, see-through material fabrication, the mobile electronic device is adapted to be inserted laterally into the pocket with its display screen aligned along an inside surface of the user's forearm. While shown as being on the inside surface of the left forearm of the user, the sleeve could be worn equally as well on the right forearm, again with the mobile device inserted laterally into the pocket with the display screen aligned—this time, along an inside surface of the right forearm.

As thus constructed, the armband carrier of the invention—or simply Armband—is particularly attractive for use by a motorist, a cyclist or a horseman. With their arms extended forward to hold on to a steering wheel, handle bars or reins, all that becomes necessary to view a communication device's display screen is to rotate the forearm outwardly from the body at only a slight angle to view the display screen 28. If a text message or voice communication is being received, a user could see who it is from, and whether it should be answered or not almost instantly, without taking his/her eyes off the road ahead. Touching the speaker phone button then allows almost instantaneous voice communication, while continuing on the driver's way. Similarly, if its a text communication, the operator becomes alerted to move to the side of the road to stop to view the text message, or to elect to view it at a later time. Both will be seen possible with a minimum of effort, and with a minimum of distraction from observing the road traffic or horse traffic ahead. The same will be seen to be the case where the user is only interested in playing music or voice selections, whether recorded on a mobile electronic device or on the mobile electronic communication device to begin with—just reaching over to tap the applicable icon on its display screen. For a mobile electronic device offering a “camera” feature, an opening is provided at 75 within the sleeve 10 to align with the camera's lens 70 in taking photos and/or videos.

This is to be contrasted, on the other hand, with smartphone carriers specifically intended to be worn while running, jogging or at the gym, where a Velcro connection holds a smartphone in a wrap about the upper arm of the wearer, within a plastic covered pocket having a reflective stripe so as to be visible in the dark. Attempting to wear that kind of arrangement while operating a motor vehicle, a motorcycle or bicycle, or while holding on to the reins of a horse would require the user to scrunch about and twist the head to visualize a display screen when a voice or text communication is received; at such juncture, as will be evident, the user would very significantly have to take his/her eyes off the road ahead in order to see the display even if the plastic covering of the screen were cleaned and not fogged over. Besides not being readily washable, such configurations would be appreciated to be far more bulkier, and costly, than the armband carrier of the invention employing a sleeve composed of a see-through stretchable compression material fabrication.

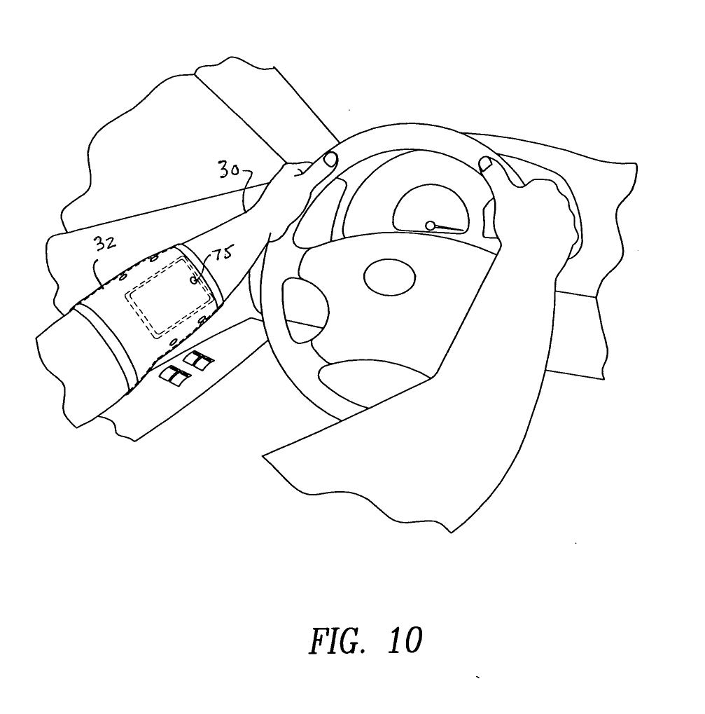

While there have been described what are considered to be preferred embodiments of the present invention, it will b appreciated by those skilled in the art that modifications can be made without departing from the scope of the teachings herein. Thus, while the armband carrier of the invention has been described in the context of fitting onto a forearm of the wearer—and thus made available in small, medium and large sizes—the sleeve 10 can be sized even larger so as to fit over the forearm of a sweater, a light-weight jacket, or even a heavy winter jacket being worn at the time, all resulting from the stretchable-compressible nature of the armband fabrication. To such extent, FIG. 10 illustrates, for example, the armband carrier being worn by a motorist—and of a construction length to extend from the wrist area 30 even beyond the elbow area 32, in providing added support in retention of the smartphone or mobile electronic device in place via the stretchable compression characteristics of the sleeve fabrication. For at least such reason, therefore, resort should be had to the claims appended hereto for a true understanding of the scope of the invention.

1. (canceled)

2. (canceled)

3. (canceled)

4. (canceled)

5. The armband of claim 15 wherein said pocket is sized to receive a mobile electronic device also capable of playing previously stored music and voice selections.

6. The armband of claim 15 wherein said sleeve is composed of a washable, stretchable compression, see-through garment material fabrication.

7. The armband of claim 6 wherein said sleeve is composed of a fiber embedded nylon.

8. (canceled)

9. (canceled)

10. (canceled)

11. (canceled)

12. The armband of claim 5 wherein said pocket is sized to receive a mobile electronic device having a camera lens capable of taking photos and videos, and wherein said sleeve includes an opening therein to align with such lens in one of said inner facing and overlain outer facing surfaces thereof.

13. The armband of claim 6 wherein said sleeve is of a length to extend along said inside body facing surface of the forearm of a wearer from a point adjacent the wrist area thereof.

14. The armband of claim 6 wherein said sleeve is of a length to extend along said inside body facing surface of the forearm of a wearer from a point adjacent the wrist area thereof to a point beyond the elbow area thereof.

15. An armband to facilitate mobile electronic device communications without impairing focused eye attention while simultaneously carrying out hand operational activities in a noise existent environment, comprising:
a sleeve having first and second open opposing ends, first and second inner facing surfaces each overlain by an outer facing surface, and an inside pocket accessible to one of said first and second opposing ends;
with said sleeve being of a length to extend along the forearm of a wearer, from a wrist area thereof towards an elbow area thereof;
with said pocket having a back surface adjacent one of said first and second inner facing surfaces, and a front surface adjacent said other of said first and second inner facing surfaces;
with said pocket being sized to receive within a mobile electronic device capable of receiving at least one of text message and voice communications;
with said first open opposing end of said sleeve being of a larger opening than said second opposing end of said sleeve;
with said sleeve and said pocket being dimensioned to align a display screen of a mobile electronic device laterally inserted into said pocket through said first open opposing end of said sleeve along an inside body facing surface of the wearer's forearm offset towards the elbow area of the wearer, closer thereto than to the wrist area of the wearer; and
with said sleeve being composed of a stretchable compression see-through garment material fabrication characterized to retain a positioning of said sleeve and pocket in place on said inside body facing surface of the forearm while the wearer is carrying out hand operational activities.

16. The armband of claim 15 wherein said sleeve is characterized to retain a positioning of said sleeve and pocket in place on said inside body facing surface of the forearm when the forearm is rotated outwardly away from the body as the wearer is carrying out such hand operational activities as holding onto the steering wheel of a motor vehicle, the handle bars of a motorcycle or the reins of a horse.
